(19) United States
(12) Patent Application Publication
(10) Pub. No.: US 2023/0051892 A1
(43) Pub. Date: Feb. 16, 2023

(54) Conductive Concrete Electric Thermal Battery

(71) Applicant: NUtech Ventures, Lincoln, NE (US)

(72) Inventor: Lim Nguyen, Pappillion, NE (US)

(73) Assignee: NUtech Ventures, Lincoln, NE (US)

(21) Appl. No.: 17/888,161

(22) Filed: Aug. 15, 2022

Related U.S. Application Data
(60) Provisional application No. 63/233,553, filed on Aug. 16, 2021.

(51) Int. Cl. F28D 20/00; H01L 35/28; H02K 7/18; H05B 3/00; C04B 14/38; C04B 14/48; F01D 15/10; E04B 1/76; E04B 2/86; E04B 5/36

(52) U.S. Cl. CPC F28D 20/0056; H01L 35/28; H02K 7/1823; H05B 3/0004; C04B 14/386; C04B 14/48; F01D 15/10; E04B 1/76; E04B 2/86; E04B 5/36; C04B 2111/94

(57) ABSTRACT

A conductive concrete electric thermal battery includes conductive concrete; and a plurality of electrodes disposed in the conductive concrete, each electrode of the plurality of electrodes is mechanically isolated from every other electrode of the plurality of electrodes and configured to connect electrically to a source of electrical energy. The conductive concrete includes a mixture of concrete and at least one conductive material.

### CROSS-REFERENCE TO A RELATED APPLICATION

This application claims priority under 35 U.S.C. § 119(e) to U.S. Provisional Application No. 63/233,553, filed Aug. 16, 2021, which is incorporated herein by reference in its entirety.

### BACKGROUND

Renewable energy such as solar and wind energy requires energy storage in order to provide electricity during periods when the sun is not shining or the wind is not blowing. Energy storage may be used to balance grid electricity generation and consumption. Energy storage technology that has been deployed includes chemical-based batteries for residential and grid-scale utilities and business applications. Pumped hydroelectricity energy storage and compressed air energy storage are other examples of grid-scale applications that have been successfully deployed.

More recently, a proof-of-system electric thermal energy storage plant has been demonstrated. For charging, the electric thermal technology employs an electric resistance heater and blows hot air through the 1,000 metric tons of volcanic rock for thermal storage, raising the temperature of the volcanic rock to 750 degrees Celsius (° C.). In this energy storage plant, electricity is used to heat air. The hot air is then blown through the volcanic rock, heating the rocks. The volcanic rocks store energy in the form of heat (i.e., stored thermal energy). For discharging the stored thermal energy, cold air blows through the high temperature volcanic rocks. The volcanic rocks transfer a portion of their thermal energy, heating the air. The heated air transfers heat to a steam boiler that drives a steam turbine to generate electricity. This storage technology can use excess solar and wind as well as utility electricity for charging and can provide electricity, heat, and process steam while discharging.

### SUMMARY

One or more embodiments of the present disclosure provide a conductive concrete electric thermal battery that includes conductive concrete that includes a mixture of concrete and at least one conductive material, and a plurality of electrodes disposed in the conductive concrete, where each electrode of the plurality of electrodes is mechanically isolated from every other electrode of the plurality of electrodes and configured to connect electrically to a source of electrical energy.

### BRIEF DESCRIPTION OF THE DRAWINGS

FIG. 1 shows a conductive concrete electric thermal battery according to one or more embodiments of the present disclosure.

FIG. 2 shows a conductive concrete electric thermal battery in a system that includes a steam turbine engine according to one or more embodiments of the present disclosure.

FIG. 3 shows a conductive concrete electric thermal battery in a system that includes a thermoelectric generator and a Stirling engine generator according to one or more embodiments of the present disclosure.

### DETAILED DESCRIPTION

One or more embodiments of the present disclosure may employ electrically conductive concrete such as that developed at the University of Nebraska. The conductive concrete may be similar to regular concrete, but the conductive concrete may also include some form of carbon and/or metal fibers/shavings (for example, steel fiber/shavings) or the like to allow the concrete to conduct electricity. The carbon may be, for example, low-grade carbonaceous material such as coke-breeze for low cost. Electrical conductance of the concrete may be controlled by varying the composition of the concrete and typically may range from a few tenths of a siemens (S) to a few siemens, though other values may be possible.

Electrically conductive concrete may be used for deicing roads and bridges, anti-static flooring/grounding, concrete structural health monitoring, electromagnetic shielding, anechoic chambers, ground planes, and the like.

Conceptually, conductive concrete enables thermal energy storage (TES) via Joule heating by using electricity to heat directly the electric thermal battery instead of hot air via electric resistance heating. Direct Joule heating may be more efficient in electrical to thermal energy conversion during charging than a hot air via electric resistance heating. In one or more embodiments, metal electrodes may be embedded in the conductive concrete to energize the concrete volume with electricity, thereby heating up the concrete and raising its temperature. The heat capacity of concrete at room temperature may be about 880 joules/kilogram/degree Celsius (J/kg/° C.) or 400 joules/pound/degree Celsius (J/lb/° C.). The mass density of concrete at 150 pounds/cubic foot (lb/ft³) yields a thermal density of 60 kilojoules/cubic foot/degree Celsius (kJ/ft³/° C.) or 1.62 megajoules/cubic yard/degree Celsius (MJ/yd³/° C.). This thermal density corresponds to a storage density of 810 MJ/yd³ or 225 kWh/yd³ at 500° C. for an example embodiment of a conductive concrete electric thermal battery. The base storage cost is thus about $2 per kWh at the cost of $450 per cubic yard of conductive concrete. Notice that the 225 kWh/yd³ storage capacity is well suited for residential applications. According to this example, a grid-level storage capacity of 1 gigawatt-hour (GWh) with conductive concrete electric thermal battery would require approximately 4,500 cubic yards at the base cost of around $2 million for the concrete. Thus, conductive concrete electric thermal battery may provide a cost effective solution for grid storage. In one or more embodiments, the concrete may be cast using an insulated concrete form (ICF) with high temperature insulation for long-term heat retention.

For grid storage applications, the one or more embodiments of the present disclosure may employ air holes that will be either cast or bored through the conductive concrete. Cold air may be blown through the high temperature concrete, gaining heat that may be used for other applications, for example, to heat water for operating a steam boiler. Steam produced in the boiler may be used to drive a steam turbine to generate electricity. Advantageously, this or other embodiments may allow existing fossil fuel power plants such as coal and gas fired power plants to be recommissioned to operate with a conductive concrete electric thermal battery as the heat source in place of burning fossil fuel.

In one or more embodiments, the conductive concrete electric thermal battery may be cast with an integrated steam boiler that has been engineered for direct heating via the high temperature concrete. This approach also allows existing nuclear reactor power plants such as pressurized water reactors and boiling water reactors to be recommissioned to operate with conductive concrete battery as the core heat source.

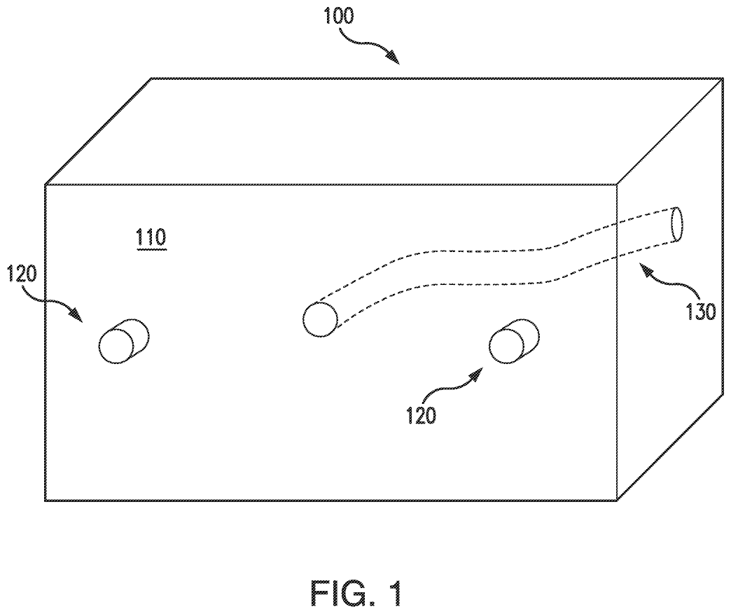

Referring to FIG. 1, in one or more embodiments, a conductive concrete electric thermal battery 100 may comprise conductive concrete 110. Although FIG. 1 shows the conductive concrete 110 in the form of a rectangular solid, other forms may be used including irregular shapes. A plurality of electrodes 120 may be disposed in the conductive concrete 110. These electrodes 120 are capable of receiving electric current from a source of electrical energy, for example, the power grid, solar farms, and wind generators. At least one fluid channel 130 passes through the conductive concrete 110. Such fluid channels 130 allows a fluid, for example, air, at a temperature below that of the conductive concrete electric thermal battery 100 to flow through the conductive concrete 110 and absorb thermal energy that may then be used elsewhere. In one or more embodiments, a fluid channel may not be necessary if heat is transferred directly from a conductive concrete electric thermal battery 100 to another device, for instance a Stirling engine or a thermoelectric generator (TEG). A TEG is a semiconductor device that generates electricity when placed in contact with a higher temperature reservoir on one side and a lower temperature reservoir on the opposite side. As an example, the higher temperature reservoir may be a mass of conductive concrete at 500° C., and the lower temperature reservoir may be a cold plate, which is maintained at a temperature of 30° C. by water flowing through it. The TEG utilizes the Seebeck effect where a temperature difference between two dissimilar electrical conductors or semiconductors produces a voltage difference between the two substances. For example, a bismuth-telluride (Bi₂Te₃) semiconductor may be used.

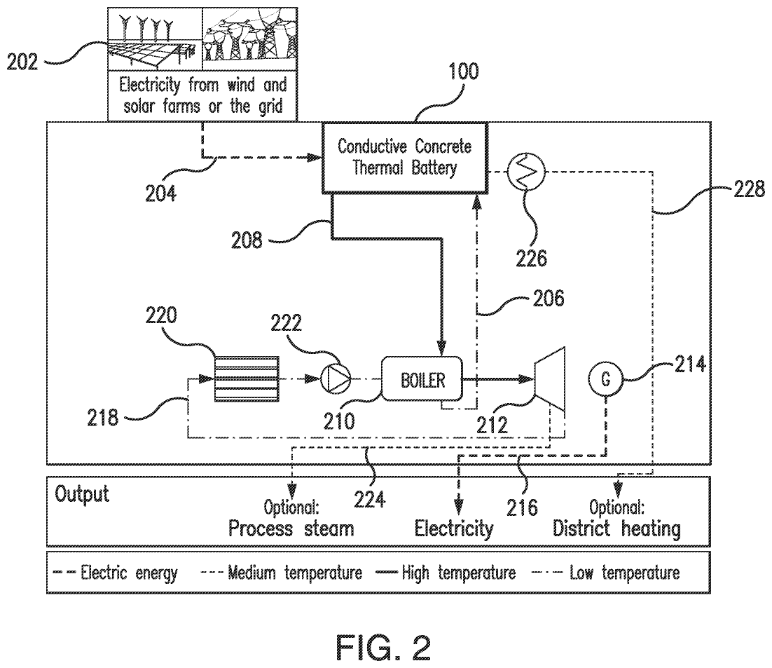

Referring to FIG. 2, a source of electrical energy 202 may transmit electrical energy 204 to a conductive concrete electric thermal battery 100. Possible energy sources may include wind and solar, whose energy outputs may vary greatly with time, as well as other sources on an electrical power grid, including fossil-fuel (for example, natural gas, oil, and coal) fired electrical power plants. Electrical energy 204 may be received by a conductive concrete electric thermal battery 100 in either the form of alternating current (AC) or direct current (DC).

Still referring to FIG. 2, energy may be stored in the conductive concrete electric thermal battery 100 by flowing AC or DC electricity through the conductive concrete electric thermal battery 100 by connecting the energy source 202 to at least two electrodes 120 embedded in the conductive concrete 110.

Thermal energy stored in the conductive concrete electric thermal battery 100 may be extracted by different means discussed in the present disclosure. In the example shown in FIG. 2, a fluid at a temperature (designated “low temperature” fluid in this example) lower than the temperature of the conductive concrete electric thermal battery 100 passes through some or all of the battery, increasing in temperature until the fluid exits that battery at a higher temperature (“high temperature” fluid 208 in this example). The fluid may be air, though other gases and liquids may be used. The conductive concrete electric thermal battery 100 may be designed with holes (for example, air holes) bored or cast into the concrete that enable the fluid to pass through the battery 100.

The high temperature fluid 208 may be used to generate steam in a boiler 210 by heating water. After transferring some of its heat in the boiler, the fluid exits the boiler at a lower temperature (“low temperature” fluid 206) and returns to the conductive concrete electric thermal battery 100 where the fluid may again be heated.

Steam at high temperature may then be used to turn a steam turbine 212 connected to an electrical generator 214 that may produce electricity 216. The steam that passes through the steam turbine will exit the steam turbine at a medium temperature (“medium temperature” fluid 218) where it can pass through a condenser 220 where a phase transition from gas to liquid (for example, steam to water) may occur and allow this liquid to again enter the boiler 210, perhaps with the aid of a pump 222, to be heated.

Process steam 224 may also be extracted from the steam turbine 212. Process steam 224 is defined as steam used for heat and moisture rather than power.

Also shown in FIG. 2 is a fluid extracted from the conductive concrete electric thermal battery 100 at a medium temperature and passing through a heat exchanger 226. This extracted thermal energy may be used for district heat 228, providing space heating and water heating for commercial and residential needs near the conductive concrete electric thermal battery 100.

For residential applications, generating electricity via a boiler-steam turbine method may be impractical. Instead, one or more embodiments of the present disclosure may employ a thermoelectric electric generator (TEG). The all solid-state thermoelectric modules in a TEG may be fabricated with semiconductor materials that generate electricity via a temperature difference between the higher temperature conductive concrete, for example, at 500° C. and the lower temperature ambient, for example, at 30° C. TEG thermal-to-electrical conversion efficiency may be rather low, perhaps less than 5%. Thus, the thermal energy storage may be sized accordingly. For example, 4 cubic yards of conductive concrete can store 900 kWh of thermal energy at 500° C. to generate 45 kWh of TEG electricity at 5-6% thermal-to-electrical conversion efficiency. In addition, the waste heat from TEG may be available for household heating and hot water. TEG conversion efficiency and cost are expected to improve as the technology deployment of the present disclosure becomes widespread.

In one or more embodiments, another discharging method by the present disclosure may employ a Stirling engine generator. A Stirling engine generator is a more efficient heat engine. With a 20% electrical conversion efficiency at 225 kWh per cubic yard the conductive concrete electric thermal battery can provide 45 kWh of storage electricity per cubic yard.

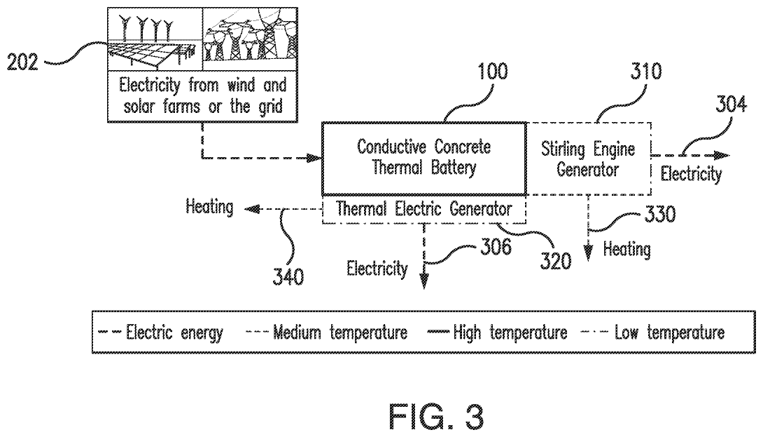

In the example shown in FIG. 3, energy sources 202 may be drawn from the same one or more candidates identified above when discussing FIG. 2. Similarly, energy may be transferred to and stored in a conductive concrete electric thermal battery 100 as discussed above. FIG. 3 provides examples of two additional ways that energy stored in a conductive concrete electric thermal battery 100 may be extracted. These two means of converting thermal energy stored in a conductive concrete electric thermal battery 100 into electrical energy 304, 306 are a Stirling engine generator 310 and a thermoelectric generator (TEG) 320. Both a Stirling engine generator 310 and a TEG 320 may provide heat 330, 340 that can be utilized in other ways as a byproduct of generating electricity.

In one or more embodiments, a conductive concrete electric thermal battery 100, included conductive concrete where the conductive concrete comprises a mixture of concrete and at least one conductive material. The conductive concrete electric thermal battery 100 may further include a plurality of electrodes 120 disposed in the conductive concrete, with each electrode of the plurality of electrodes being mechanically isolated from every other electrode of the plurality of electrodes and configured to connect electrically to a source of electrical energy.

The conductive concrete electric thermal battery 100 may further include at least one fluid channel 130 through the conductive concrete 110 originating on a first outside surface of the conductive concrete 110 and terminating on the first outside surface and/or a second outside surface of the conductive concrete 110.

In one or more embodiments, the at least one conductive material may include carbon, metal fibers/shavings, or both. The metal fiber/shavings may be, for example, steel fibers/shavings.

In one or more embodiments, the conductance of the conductive concrete may be greater than or equal to 0.1 siemens and less than or equal to 10 siemens.

The conductive concrete electric thermal battery 100 may heated by Joule heating.

In one or more embodiments, the conductive concrete electric thermal battery may be formed into structural elements configured for inclusion in a commercial, industrial, or residential structure. These structural elements may be a wall, a floor, a ceiling, or the like. The strength of conductive concrete may be greater than the strength of concrete without the addition of conductive materials. For example, some conductive concrete is twice as strong as concrete without the conductive materials.

The conductive concrete electric thermal battery may further include insulating material that at least partially surrounds the conductive concrete. The insulating material may include an insulated concrete form, and the conductive concrete may be cast using the insulated concrete form.

In one or more embodiments, method of storing thermal energy in the conductive concrete electric thermal battery may include Joule heating the conductive concrete electric thermal battery by passing an electric current through the conductive concrete.

In one or more embodiments, a system of supplying thermal energy stored in a conductive concrete electric thermal battery to generate electricity may include the conductive concrete electric thermal battery, a steam electric generator that generates electricity and includes a boiler, and closed fluid loop that includes a fluid that passes through one or more fluid channels of the conductive concrete electric thermal battery and transfers heat to the boiler. The steam electric generator may be part of a decommissioned nuclear power plant or part of a decommissioned fossil-fuel fired power plant.

In one or more embodiments, a system of supplying thermal energy stored in the conductive concrete electric thermal battery to generate electricity may include a conductive concrete electric thermal battery and a Stirling engine generator that generates electricity and makes thermal contact with the conductive concrete electric thermal battery, where the conductive concrete electric thermal battery is a high temperature reservoir for the Stirling engine generator.

In one or more embodiments a system of supplying thermal energy stored in a conductive concrete electric thermal battery to generate electricity may include a conductive concrete electric thermal battery and a thermoelectric generator. The thermoelectric generator may include more than one semiconductor material and may make thermal contact with the conductive concrete electric thermal battery. That is, the conductive concrete electric thermal battery may be a high temperature reservoir for the thermoelectric generator.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A conductive concrete electric thermal battery, comprising:
conductive concrete comprising a mixture of concrete and at least one conductive material; and
a plurality of electrodes disposed in the conductive concrete, each electrode of the plurality of electrodes is mechanically isolated from every other electrode of the plurality of electrodes and configured to connect electrically to a source of electrical energy.

2. The battery of claim 1, further comprising at least one fluid channel through the conductive concrete originating on a first outside surface of the conductive concrete and terminating on the first outside surface and/or a second outside surface of the conductive concrete.

3. The battery of claim 1, wherein the at least one conductive material comprises a member of the group consisting of carbon and metal fibers/shavings.

4. The battery of claim 3, wherein the at least one conductive material comprises both carbon and metal fibers/shavings.

5. The battery of claim 3, wherein the metal fiber/shavings are steel fibers/shavings.

6. The battery of claim 1, wherein the conductance of the conductive concrete is greater than or equal to 0.1 siemens and less than or equal to 10 siemens.

7. The battery of claim 1, wherein the battery is heated by Joule heating.

8. The battery of claim 1, wherein the battery is formed into structural elements configured for inclusion in a commercial, industrial, or residential structure.

9. The battery of claim 8, wherein the structural elements comprise at least one member of the group consisting of a wall, a floor, and a ceiling.

10. The battery of claim 1, further comprising insulating material at least partially surrounding the conductive concrete.

11. The battery of claim 10, wherein:
the insulating material comprises an insulated concrete form, and
wherein the conductive concrete is cast using the insulated concrete form.

12. A method of storing thermal energy in the conductive concrete electric thermal battery of claim 1, comprising Joule heating the conductive concrete electric thermal battery by passing an electric current through the conductive concrete.

13. A system of supplying thermal energy stored in the conductive concrete electric thermal battery of claim 2 to generate electricity, comprising:
the conductive concrete electric thermal battery;
a steam electric generator that generates electricity and comprises a boiler; and
a closed fluid loop comprising a fluid that passes through the at least one fluid channel of the conductive concrete electric thermal battery and transfers heat to the boiler.

14. The system of claim 13, wherein the steam electric generator is disposed in a decommissioned nuclear power plant.

15. The system of claim 13, wherein the steam electric generator is disposed in a decommissioned fossil-fuel fired power plant.

16. A system of supplying thermal energy stored in the conductive concrete electric thermal battery of claim 1 to generate electricity, comprising:
the conductive concrete electric thermal battery; and
a Stirling engine generator that generates electricity and makes thermal contact with the conductive concrete electric thermal battery,
wherein the conductive concrete electric thermal battery is a high temperature reservoir for the Stirling engine generator.

17. A system of supplying thermal energy stored in the conductive concrete electric thermal battery of claim 1 to generate electricity, comprising:
the conductive concrete electric thermal battery; and
a thermoelectric generator comprising a plurality of semiconductor materials and makes thermal contact with the conductive concrete electric thermal battery,
wherein the conductive concrete electric thermal battery is a high temperature reservoir for the thermoelectric generator.
